(19) United States
(12) Patent Application Publication
(10) Pub. No.: US 2025/0234599 A1
(43) Pub. Date: Jul. 17, 2025

(54) SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 18/957,831

(22) Filed: Nov. 24, 2024

(30) Foreign Application Priority Data
Jan. 12, 2024 (JP) 2024-003558

(51) Int. Cl. H01L 23/528; H01L 23/532

(52) U.S. Cl. CPC H10D 62/103; H01L 23/5283; H01L 23/53266; H10D 12/481; H10D 64/231

(57) ABSTRACT

Provided is a semiconductor device including: an interlayer dielectric film provided above a semiconductor substrate; a front surface electrode provided above the semiconductor substrate; a contact portion at which the front surface electrode and the mesa portion are connected in a contact hole of the interlayer dielectric film; and a lifetime adjustment region provided in a front surface side of the semiconductor substrate, where the contact portion includes a first contact portion provided in the transistor portion and a second contact portion provided in the diode portion, and the first contact portion is arranged at an upper side than the second contact portion.

The contents of the following patent application(s) are incorporated herein by reference: NO. 2024-003558 filed in JP on Jan. 12, 2024

### BACKGROUND

### 1. TECHNICAL FIELD

The present invention relates to a semiconductor device.

### 2. RELATED ART

A semiconductor device is known having a structure including a transistor portion and a diode portion, where an electrode and a semiconductor substrate are connected at a trench-shaped contact (for example, refer to Patent Documents 1 and 2.)
Patent Document 1: WO 2018/056233
Patent Document 2: Japanese Patent Application Publication No. 2021-150483

### BRIEF DESCRIPTION OF THE DRAWINGS

FIG. 1 is a plan view showing an example of a semiconductor device 100.

FIG. 2 is an enlarged view of an example of a region D in FIG. 1.

FIG. 3A is a diagram showing an example of a cross section a-a in FIG. 2.

FIG. 3B is an enlarged view showing in the vicinity of the contact hole 54 provided in the first mesa portion 61, the third mesa portion 63 and the fourth mesa portion 64 shown in FIG. 3A.

FIG. 4A is a diagram showing an example of a cross section b-b in FIG. 2.

FIG. 4B is an enlarged view showing in the vicinity of the contact hole 54 provided in the first mesa portion 61, the third mesa portion 63 and the fourth mesa portion 64 shown in FIG. 4A.

FIG. 4C is a diagram showing another example of the cross section b-b in FIG. 2.

FIG. 4D is an enlarged view showing in the vicinity of the contact hole 54 provided in the first mesa portion 61, the third mesa portion 63 and the fourth mesa portion 64 shown in FIG. 4C.

FIG. 5A is a diagram showing another example of the cross section a-a in FIG. 2.

FIG. 5B is a diagram showing another example of the cross section b-b in FIG. 2.

FIG. 6 is an enlarged view showing another example of the region D in FIG. 1.

FIG. 7A is a diagram showing an example of a cross section c-c in FIG. 6.

FIG. 7B is a diagram showing an example of a cross section d-d in FIG. 6.

FIG. 8 is an enlarged view showing another example of the region D in FIG. 1.

FIG. 9A is a diagram showing an example of a cross section e-e in FIG. 8.

FIG. 9B is an enlarged view in the vicinity of the first mesa portion 61, the second mesa portion 62, the third mesa portion 63 and the fourth mesa portion 64 shown in FIG. 9A.

FIG. 9C is a diagram showing an example of a cross section f-f in FIG. 8.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the-Z axis direction are directions opposite to each other. When the Z axis direction is described without describing the signs, it means that the direction is parallel to the +Z axis and the-Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

A region from the center of the semiconductor substrate in the depth direction to the front surface of the semiconductor substrate may be referred to as a front surface side. Similarly, a region from the center of the semiconductor substrate in the depth direction to the back surface of the semiconductor substrate may be referred to as a back surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of an N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. In the present specification, the VOH defect or interstitial Si—H may be referred to as a hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur, but the invention is not limited to these. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10^{17/}cm³. The oxygen concentration contained in the substrate manufactured by the FZ method is 1×10¹⁵ to 5×10^{16/}cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (D0) of the non-doped substrate is, for example, from 1×10^{10/}cm³ or more and to 5×10^{12/}cm³ or less. The bulk donor concentration (D0) of the non-doped substrate is preferably 1×10^{11/}cm³ or more. The bulk donor concentration (D0) of the non-doped substrate is preferably 5×10^{12/}cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of a P type or an N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

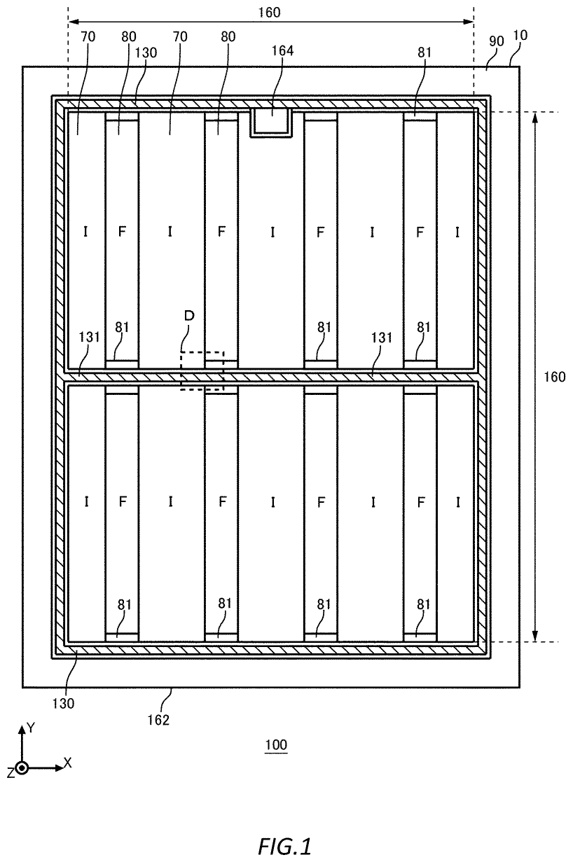

FIG. 1 is a plan view showing an example of a semiconductor device 100. FIG. 1 illustrates a position of each member as being projected onto a front surface of a semiconductor substrate 10. FIG. 1 shows merely some members of the semiconductor device 100, and omits other members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top plan view. As simply used herein, unless otherwise specified, a top plan view means a view from the side of the front surface of the semiconductor substrate 10. The semiconductor substrate 10 in this example has two sets of end sides 162 opposite to each other in a top plan view. In FIG. 1, the X axis and the Y axis are parallel to any of the end sides 162. In addition, the Z axis is perpendicular to the front surface of the semiconductor substrate 10.

The semiconductor substrate 10 is provided with an active portion 160. The active portion 160 is a region where a principal current flows in the depth direction between the front surface and the back surface of the semiconductor substrate 10 when the semiconductor device 100 operates. An emitter electrode is provided above the active portion 160, but is omitted in FIG. 1. The active portion 160 may refer to a region that overlaps with the emitter electrode in the top plan view. In addition, a region sandwiched between active portions 160 in a top plan view may also be included in the active portion 160.

The active portion 160 is provided with a transistor portion 70 including a transistor element such as an insulated gate bipolar transistor (IGBT) and a diode portion 80 including a diode element such as a freewheeling diode (FWD). In the example of FIG. 1, along a predetermined first direction (X axis direction in the present example) on the front surface of the semiconductor substrate 10, the transistor portions 70 and the diode portions 80 are arranged alternately. The semiconductor device 100 in this example is a reverse-conducting IGBT (RC-IGBT). A boundary region is arranged between the transistor portion 70 and the diode portion 80 in the X axis direction, but is omitted in FIG. 1.

In FIG. 1, a region where each of the transistor portions 70 is arranged is indicated by a symbol “I”, and a region where each of the diode portions 80 is arranged is indicated by a symbol “F”. In the present specification, a direction different from the first direction in the top plan view may be referred to as a second direction (the Y axis direction in FIG. 1). The second direction may be a direction perpendicular to the first direction. Each of the transistor portion 70 and the diode portion 80 may have a longitudinal length in the second direction. In other words, the length of each of the transistor portions 70 in the Y axis direction is larger than the width in the X axis direction. Similarly, the length of each of the diode portions 80 in the Y axis direction is larger than the width in the X axis direction. The second direction of the transistor portion 70 and the diode portion 80 may be the same as a longitudinal direction of each trench portion and a longitudinal direction of the mesa portion which will be described below.

The diode portion 80 includes a cathode region of N+ type in a region in contact with the back surface of the semiconductor substrate 10. In the present specification, a region where the cathode region is provided is referred to as the diode portion 80. In other words, the diode portion 80 is a region that overlaps with the cathode region in the top plan view. The back surface of the semiconductor substrate 10 may be provided with a collector region of P+ type in a region other than the cathode region. In the present specification, the diode portion 80 may also include an extension region 81 where the diode portion 80 extends to a gate runner described below in the Y axis direction. The back surface of the extension region 81 is provided with the collector region. The diode portion 80 includes an anode region of a P− type in the front surface side of the semiconductor substrate 10.

The transistor portion 70 includes a collector region of a P+ type in a region in contact with the back surface of the semiconductor substrate 10. In addition, the transistor portion 70 includes emitter regions of the N type, contact regions of the P+ type, base regions of the P− type, and gate structures including gate conductive portions and gate dielectric films arranged regularly in the front surface side of the semiconductor substrate 10.

The semiconductor device 100 may have one or more pads above the semiconductor substrate 10. The semiconductor device 100 in this example has a gate pad 164. The semiconductor device 100 may include pads such as an anode pad and a cathode pad of a temperature sensing portion configuring a PN junction diode and a current detection pad. Each pad is arranged in the vicinity of the end side 162. The vicinity of the end side 162 refers to a region between the end side 162 and the emitter electrode in a top plan view. When the semiconductor device 100 is mounted, each pad may be connected to an external circuit through a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of the present example includes an outer circumferential gate runner 130. The outer circumferential gate runner 130 is arranged between the active portion 160 and the end side 162 of the semiconductor substrate 10 in a top plan view. The outer circumferential gate runner 130 in this example encloses the active portion 160 in a top plan view. A region enclosed by the outer circumferential gate runner 130 in a top plan view may be defined as the active portion 160. In addition, a well region is formed below the gate runner. The well region is a P type region having a concentration higher than that of a base region which will be described below and formed from the front surface of the semiconductor substrate 10 to a position deeper than that of the base region. A region enclosed by the well region in a top plan view may be the active portion 160.

An outer circumferential gate runner 130 is connected to the gate pad 164. The outer circumferential gate runner 130 is arranged above the semiconductor substrate 10. The outer circumferential gate runner 130 may be a metal wiring including aluminum or the like or a semiconductor such as polysilicon doped with impurities.

The semiconductor device 100 of the present example further includes an active-side gate runner 131. The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runners 130 and the active-side gate runner 131 are connected to the gate trench portion of the active portion 160. The outer circumferential gate runners 130 and the active-side gate runner 131 are arranged above the semiconductor substrate 10. The outer circumferential gate runner 130 and the active-side gate runner 131 may be a metal wiring including aluminum or the like or a wiring formed of a semiconductor such as polysilicon doped with impurities.

The active-side gate runner 131 may be connected to the outer circumferential gate runner 130. The active-side gate runner 131 in this example is provided extending in the X axis direction so as to cross the active portion 160 substantially at the center of the Y axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X axis direction in each divided region.

The semiconductor device 100 may include a temperature sensing portion (not shown) which is a PN junction diode formed of polysilicon or the like, and a current detection portion (not shown) which simulates an operation of a transistor portion provided in the active portion 160. The temperature sensing portion may include an anode pad and a cathode pad arranged in the vicinity of the end side 162. In addition, the current detection portion may include a current detection pad arranged in the vicinity of the end side 162.

The semiconductor device 100 in this example includes an edge termination structure portion 90 between the active portion 160 and the end side 162 in a top plan view. The edge termination structure portion 90 in this example is arranged between the outer circumferential gate runner 130 and the end side 162. The edge termination structure portion 90 reduces the electric field strength in the front surface side of the semiconductor substrate 10. The edge termination structure portion 90 may include at least one of a guard ring, a field plate, and an RESURF which are annularly provided enclosing the active portion 160.

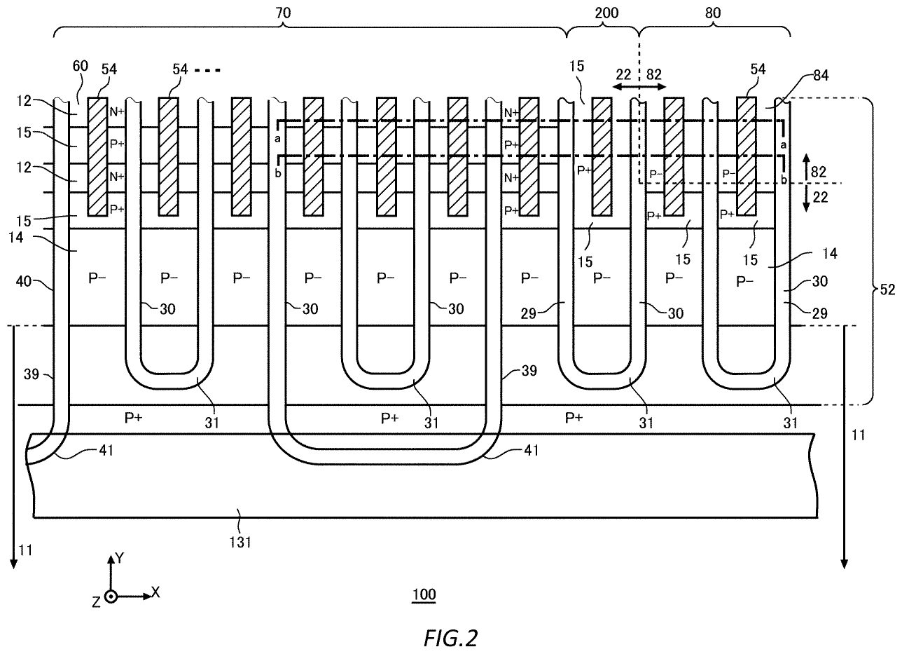

FIG. 2 is an enlarged view of an example of a region D in FIG. 1. The region D is a region including a transistor portion 70, a diode portion 80, and an active-side gate runner 131. Although omitted in FIG. 1, a boundary region 200 is arranged between the transistor portion 70 and the diode portion 80 in the X axis direction. The boundary region 200 is a buffer structure such that different structures of the transistor portion 70 and the diode portion 80 are arranged in parallel. The boundary region 200 is a region which includes a collector region of a P+type in a region in contact with the back surface of the semiconductor substrate 10. The boundary region 200 of the present example does not include the emitter region on the front surface of the semiconductor substrate 10.

The semiconductor device 100 of this example includes a gate trench portion 40, a dummy trench portion 30, a well region 11, an emitter region 12, a base region 14, a contact region 15, and an anode region 84 that are provided inside the front surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the front surface of the semiconductor substrate 10. The emitter electrode 52 and the active-side gate runner 131 are provided in isolation from each other.

An interlayer dielectric film is provided between the emitter electrode 52 and the active-side gate runner 131, and the front surface of the semiconductor substrate 10, but the interlayer dielectric film is omitted in FIG. 2. In the interlayer dielectric film of this example, a contact hole 54 is provided extending through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, the contact region 15 and the anode region 84. The emitter electrode 52 is in contact with the emitter region 12, the contact region 15, and the base region 14 on the front surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. The emitter electrode 52 is an example of a front surface electrode. FIG. 2 shows a range where the emitter electrode 52 is provided. For example, at least a partial region of the emitter electrode 52 is formed of aluminum or an alloy containing aluminum as a main component, such as a metal alloy of Al—Si or Al—Si—Cu alloy, for example, copper or an alloy containing copper as a main component, or the like. The front surface electrode may include a barrier metal. Further, the front surface electrode may include: a contact plug portion in the contact hole, including a barrier metal formed of titanium, a titanium compound and the like on a side surface of the contact hole; and a plug formed by embedding tungsten, copper or the like to be in contact with the barrier metal and the emitter electrode 52. The contact plug portion connects the emitter electrode 52 and the semiconductor substrate 10. The plug and the emitter electrode 52 may be formed integrally.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y axis direction toward the active-side gate runner 131 side. The well region 11 is a region of a second conductivity type having a higher doping concentration than the base region 14. The base region 14 of this example is a P− type, and the well region 11 is a P+ type.

Each of the transistor portion 70, the diode portion 80, and the boundary region 200 includes a plurality of trench portions arranged in the first direction. In the transistor portion 70 of this example, one or more gate trench portions 40 and one or more dummy trench portions 30 are alternately provided along the first direction. In the diode portion 80 of this example, the plurality of dummy trench portions 30 are provided along the first direction. In the diode portion 80 in this example, the gate trench portion 40 is not provided. In the boundary region 200 of this example, the plurality of dummy trench portions 30 are provided along the first direction. In the boundary region 200 of this example, the gate trench portion 40 is not provided.

The gate trench portion 40 of this example may have two linear portions 39 extending along the second direction perpendicular to the first direction (portions of a trench that are linear along the second direction), and the edge portion 41 connecting the two linear portions 39. The second direction in FIG. 2 is the Y axis direction.

At least a part of the edge portion 41 is preferably provided in a curved shape in a top plan view. By connecting between end portions of the two linear portions 39 in the Y axis direction by the edge portion 41, it is possible to reduce the electric field strength at the end portions of the linear portions 39.

In the transistor portion 70, the dummy trench portion 30 is provided between the respective linear portions 39 of the gate trench portion 40. Between the respective linear portions 39, one dummy trench portion 30 may be provided, or a plurality of dummy trench portions 30 may be provided. In the present example, two dummy trench portions 30 are provided between the respective linear portions 39 in the transistor portion 70. The dummy trench portion 30 may have a straight shape extending in the second direction, or may have linear portions 29 and an edge portion 31 similar to the gate trench portion 40. Although the semiconductor device 100 shown in FIG. 2 only includes the dummy trench portion 30 including the edge portion 31, it may include both of the straight shaped dummy trench portion 30 not including the edge portion 31 and the dummy trench portion 30 including the edge portion 31.

A diffusion depth of the well region 11 may be deeper than the depth of the gate trench portion 40 and the dummy trench portion 30. End portions of the gate trench portion 40 and the dummy trench portion 30 in the Y axis direction are provided in the well region 11 in the top plan view. In other words, the bottom portion in a depth direction of each trench portion is covered with the well region 11 at the end portion in the Y axis direction of each trench portion. With this configuration, the electric field strength on the bottom portion of each trench portion can be reduced.

A mesa portion 60 is provided between the trench portions adjacent in the first direction. The mesa portion 60 refers to a region sandwiched between the trench portions inside the semiconductor substrate 10. A front surface of the mesa portion 60 of the present example is the front surface of the semiconductor substrate 10. A depth position of a lower end of the mesa portion 60 is the same as a depth position of a lower end of the trench portion. The mesa portion 60 of the present example is provided on the front surface of the semiconductor substrate 10 to extend in the second direction (the Y axis direction) along the trench. The mesa portion 60 of the transistor portion 70, the mesa portion 60 of the diode portion 80, and the mesa portion 60 of the boundary region 200 may have different structures. When merely referred to as the mesa portion 60 in the present specification, each of the mesa portion 60 of the transistor portion 70, the mesa portion 60 of the diode portion 80, and the mesa portion 60 of the boundary region 200 is referred to.

The mesa portions 60 of the transistor portion 70 and the boundary region 200 are provided with the base region 14 and the mesa portion 60 of the diode portion 80 is provided with the base region 14 and the anode region 84. While FIG. 2 shows the base region 14 arranged at one end portion of each mesa portion in the second direction, the base region 14 is also arranged at the other end portion of each mesa portion. In the mesa portion of the transistor portion 70, in the top plan view, at least one of the emitter region 12 of the first conductivity type and the contact region 15 of the second conductivity type may be provided in a region interposed between the base regions 14. The emitter region 12 in this example is the N+ type, and the contact region 15 is the P+ type. The emitter region 12 and the contact region 15 may be provided between the base region 14 and the front surface of the semiconductor substrate 10 in the depth direction.

The mesa portion 60 of the transistor portion 70 includes the emitter region 12 exposed to the front surface of the semiconductor substrate 10. The emitter region 12 is provided in contact with the gate trench portion 40. The mesa portion 60 in contact with the gate trench portion 40 may be provided with the contact region 15 exposed to the front surface of the semiconductor substrate 10.

Each of the contact region 15 and the emitter region 12 in the mesa portion 60 is provided from one trench portion to the other trench portion in the X axis direction. As an example, the contact region 15 and the emitter region 12 of the mesa portion 60 are alternately arranged along the second direction of the trench portion (the Y axis direction).

In another example, the contact region 15 and the emitter region 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12. The mesa portions 60 of the diode portion 80 and the boundary region 200 of the present example are not provided with the emitter region 12.

The contact region 15 and the anode region 84 may be provided on the front surface of the mesa portion 60 of the diode portion 80 of the present example. The anode region 84 of the diode portion 80 may be provided between the base regions 14 in the second direction (the Y axis direction), and the contact region 15 of the diode portion 80 may be provided between the base region 14 and the anode region 84 in the second direction (the Y axis direction.)

A doping concentration of the anode region 84 may be the same as or may be different from a doping concentration of the base region 14. The doping concentration of the anode region 84 of the present example is the same as the doping concentration of the base region 14. The base region 14 and the anode region 84 of the present example is of the P− type. The base region 14 and the anode region 84 can be formed in the same process, which facilitates the fabrication.

The contact region 15 may be provided on the front surface of the mesa portion 60 of the boundary region 200 of the present example. The contact region 15 of the boundary region 200 may be interposed between the base regions 14 in the second direction (the Y axis direction.) Alternatively, the anode region 84 may be provided on the front surface of the mesa portion 60 of the boundary region 200, which is the same as that of the mesa portion 60 of the diode portion 80. Alternatively, an N type impurity region may be provided in the mesa portion 60 of the boundary region 200, having the same doping concentration as that of the emitter region 12 or having a doping concentration lower than that of the emitter region 12. Note that in that case, the boundary region 200 is not provided with the gate trench portion 40. Moreover, the trench portion at the boundary position between the transistor portion 70 and the boundary region 200 is the dummy trench portion 30. In the mesa portion 60 of the boundary region 200 where the N type impurity region is not in contact with the gate trench portion 40, an inversion layer for being brought into a conductive state is not formed.

An area ratio of the contact region 15 in the mesa portion 60 of the boundary region 200 may be greater than an area ratio of the contact region 15 in the mesa portion 60 of the diode portion 80. In this case, holes in the semiconductor substrate 10 can easily be extracted via the mesa portion 60 of the boundary region 200 to the emitter electrode 52.

On the upper side of each mesa portion 60, the contact hole 54 is provided. The contact hole 54 is arranged in the region interposed between the base regions 14 or the anode regions. The contact hole 54 of the present example is provided above respective regions of the contact region 15, the base region 14, and the emitter region 12. The contact hole 54 is not provided in the base region 14 or the well region 11. The contact hole 54 may be arranged at the center of the mesa portion 60 in the first direction (the X axis direction).

In the diode portion 80, a cathode region 82 of the N+ type is provided in a region in direct contact with the back surface of the semiconductor substrate 10. In the back surface of the semiconductor substrate 10, a region in which the cathode region 82 is not provided may be provided with a collector region 22 of the P+ type. The cathode region 82 and the collector region 22 are provided between the back surface 23 of the semiconductor substrate 10 and the buffer region 20. In FIG. 2, a boundary between the cathode region 82 and the collector region 22 is indicated by a dotted line.

The cathode region 82 is arranged away from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

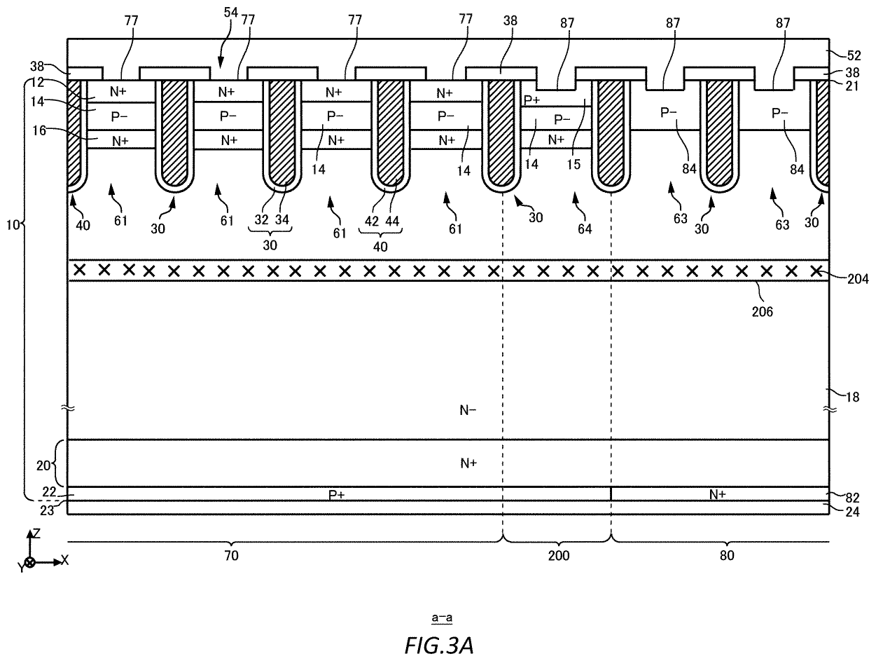

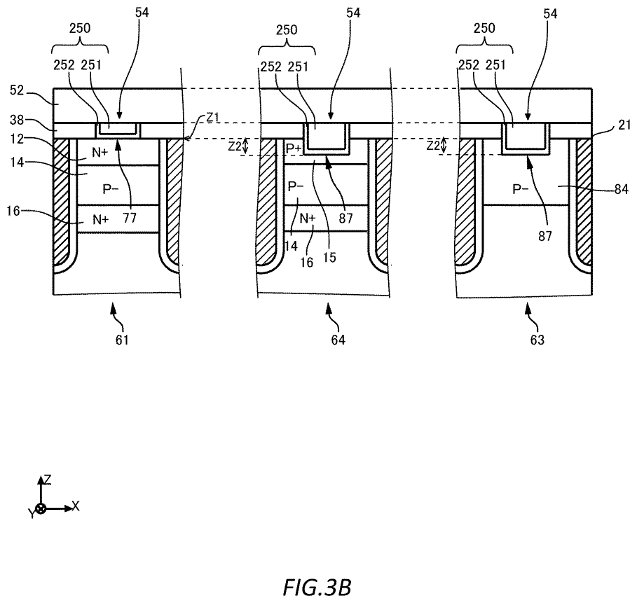

FIG. 3A is a diagram showing an example of a cross section a-a in FIG. 2. The cross section a-a is an XZ plane passing through the emitter region 12 and the cathode region 82. A semiconductor device 100 in this example includes a semiconductor substrate 10, an interlayer dielectric film 38, an emitter electrode 52, and a collector electrode 24 in the cross section.

The interlayer dielectric film 38 is provided on the front surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54 described with reference to FIG. 2.

The emitter electrode 52 is provided above the interlayer dielectric film 38. The emitter electrode 52 is an example of the front surface electrode. The emitter electrode 52 may be in contact with the semiconductor substrate 10 through the contact hole 54 of the interlayer dielectric film 38. Alternatively, the contact plug portion may be provided in the contact hole 54 to connect the emitter electrode 52 and the semiconductor substrate 10. The contact plug portion may include a plug formed of tungsten or the like and a barrier metal provided in a portion in contact with the semiconductor substrate 10 and including titanium. The barrier metal may include a titanium nitride layer and may also have a stacked structure of a titanium nitride layer and a titanium layer.

The collector electrode 24 is provided on the back surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 includes an N-type drift region 18. The drift region 18 is provided in each of the transistor portion 70, the diode portion 80, and the boundary region 200.

In the present example, the first mesa portion 61, the third mesa portion 63, and the fourth mesa portion 64 are included a plurality of mesa portions 60. The first mesa portion 61 is provided in the transistor portion 70, the third mesa portion 63 is provided in the diode portion 80, and the fourth mesa portion 64 is provided in the boundary region 200.

In the first mesa portion 61 of the transistor portion 70, the emitter region 12 of the N+ type and the base region 14 of the P− type are provided in order from the front surface 21 side of the semiconductor substrate 10. The drift region 18 is provided below the base region 14. The first mesa portion 61 may be provided with an accumulation region 16 of the N+ type. The accumulation region 16 is arranged between the base region 14 and the drift region 18.

The emitter region 12 is exposed to the front surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the first mesa portion 61.

The accumulation region 16 is provided below the base region 14. The accumulation region 16 is a region of the N+ type having a higher doping concentration than the drift region 18. That is, the accumulation region 16 has a higher donor concentration than the drift region 18. Providing the accumulation region 16 having a high concentration between the drift region 18 and the base region 14 can increase a carrier injection enhancement effect (IE effect) and reduce an on-voltage. The accumulation region 16 may be provided to cover the entire back surface of the base region 14 in the first mesa portion 61.

In the third mesa portion 63 of the diode portion 80, the anode region 84 is provided in contact with the front surface 21 of the semiconductor substrate 10. The doping concentration of the anode region 84 may be the same as the doping concentration of the base region 14 or may be lower than the doping concentration of the base region 14. The doping concentration of the anode region 84 of the present example is the same as the doping concentration of the base region 14. The base region 14 and the anode region 84 of the present example are of the P− type. The drift region 18 is provided below the anode region 84. The accumulation region 16 may be provided below the anode region 84.

In the fourth mesa portion 64 of the boundary region 200 of the present example, the base region 14 is provided and the contact region 15 is provided in the front surface side of the base region 14. The contact region 15 is interposed between the base regions 14 in the second direction (the Y axis direction.)

This facilitates to extract holes in the semiconductor substrate 10 via the fourth mesa portion 64 of the boundary region 200 to the emitter electrode 52 during the turn-off operation. The drift region 18 is provided below the base region 14. In the fourth mesa portion 64, the accumulation region 16 may be provided below the base region 14.

Note that FIG. 3A shows the boundary region 200 including one fourth mesa portion 64, but this is not limited thereto. The boundary region 200 may be provided across one or a couple of mesa portions 60 (the fourth mesa portion 64.)

In each of the transistor portion 70, the diode portion 80, and the boundary region 200, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (the Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor portion 70, t the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is boron or aluminum, for example.

In the diode portion 80, the cathode region 82 of the N+ type is provided below the buffer region 20. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

In the boundary region 200, the collector region 22 of the P+ type is provided below the buffer region 20. That is, the boundary region 200 may be regarded as a part of the transistor portion 70. The collector region 22 of the boundary region 200 may have the same doping concentration as that of the boundary region 200 of the transistor portion 70. A boundary position between the cathode region 82 and the collector region 22 in the X axis direction may be defined as a boundary position between the diode portion 80 and the boundary region 200 in the X axis direction.

In another example, in the boundary region 200, a part of or all of the collector region 22 may be replaced with the cathode region 82. When the cathode region 82 is provided on the back surface of the boundary region 200, a region of which the contact regions 15 and the anode regions 84 are arranged alternately in a region interposed between the anode regions 84 may be defined as the diode portion 80 and a region of which the contact region 15 is arranged in the entire region interposed between the anode regions 84 may be defined as the boundary region 200. When the cathode region 82 is provided on the back surface of the boundary region 200, the boundary region 200 may be regarded as a part of the diode portion 80.

From among two trench portions in contact with the emitter region 12 arranged to be closest to the diode portion 80 in the X axis direction, the trench portion at the diode portion 80 side may be the dummy trench portion 30. In this case, the dummy trench portion 30 may be defined as a boundary position between the transistor portion 70 and the boundary region 200 (or the diode portion 80) in the X axis direction. The center position of this dummy trench portion 30 in the X axis direction may be defined as a boundary position between the transistor portion 70 and the boundary region 200 (or the diode portion 80) in the X axis direction.

The boundary region 200 may alternatively be provided with the emitter region 12. Note that in that case, the boundary region 200 is not provided with the gate trench portion 40. Moreover, the trench portion at the boundary position between the transistor portion 70 and the boundary region 200 is the dummy trench portion 30. In other words, transistor operations do not occur in the boundary region 200. The boundary region 200 may alternatively be provided with the gate trench portion 40. Note that in that case, the boundary region 200 is not provided with the emitter region 12. In other words, transistor operations do not occur in the boundary region 200.

The collector region 22 and the cathode region 82 are exposed to the back surface 23 of the semiconductor substrate 10 and are connected to the collector electrode 24. The collector electrode 24 may be in contact with the entire back surface 23 of the semiconductor substrate 10. The emitter electrode 52 and the collector electrode 24 are formed of a metal material such as aluminum.

The semiconductor device 100 of this example includes a lifetime adjustment region 206 containing a lifetime killer that adjusts a lifetime of carriers. The lifetime adjustment region 206 of this example is a region where a lifetime of charge carriers is locally small. The charge carriers are electrons or holes. The charge carriers may be simply referred to as carriers. The lifetime adjustment region 206 of the present example is formed by irradiating a particle ray. Here, when merely a particle ray is referred to, it includes a particle ray formed of charged particles such as helium ions and protons and an electron beam. The lifetime adjustment region 206 of the present example is formed by implanting a particle ray from the front surface 21 side of the semiconductor substrate 10. The particle ray may also be implanted from the back surface 23 side of the semiconductor substrate 10.

In the present example, a concentration distribution of helium or the like in the depth direction of the semiconductor substrate 10 may have a flared shape from the lifetime adjustment region 206 to the front surface 21 of the semiconductor substrate 10. That is, a concentration of helium or the like (/cm³) may be decreased constantly from the lifetime adjustment region 206 to the front surface 21. The concentration of helium or the like may be larger than 0 on the front surface 21. On the other hand, the concentration of helium or the like may also have a flared shape in a direction from the lifetime adjustment region 206 to the back surface 23. Note that the flared shape toward the back surface 23 shows a shaper decrease of the concentration of helium or the like than the flared shape toward the front surface 21. The concentration of helium or the like on the back surface 23 is lower than the concentration of helium or the like on the front surface 21. The concentration of helium or the like on the front surface 21 may be equal to or smaller than the lower measurement limit or may be 0.

A particle ray is irradiated onto the semiconductor substrate 10 to implant charged particles such that lattice defects 204 such as vacancies are formed in the vicinity of implanting positions. The lattice defects 204 generate recombination centers. The lattice defects 204 may be mainly composed of vacancies such as monatomic vacancies or monovacancies (V) or diatomic vacancies or divacancies (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy-type lattice defects, vacancy-type defects, or simply lattice defects. In the present specification, the lattice defects 204 may be simply referred to as recombination centers or lifetime killers as recombination centers contributing to recombination of carriers. The lifetime killers may be formed by implanting helium ions into the semiconductor substrate 10. A chemical concentration of helium may be defined as a density of the lattice defects 204. Note that since the lifetime killer formed by implanting helium ions may be terminated by hydrogen existing in the buffer region 20, the depth position of the density peak of the lifetime killer may not be identical to the depth position of the helium chemical concentration peak. In addition, when implanting hydrogen ions into the semiconductor substrate 10, the lifetime killer may be formed in a passed-through region of hydrogen ions that is more on the implantation surface side than the projected range of hydrogen ions.

The lattice defect 204 is an example of the lifetime killer. In FIG. 3A, the lattice defects 204 at the implanting positions of charged particles are schematically indicated by symbols of x. In a region where many lattice defects 204 remain, the carriers are captured by the lattice defects 204, and thus the lifetime of the carriers is shortened. By adjusting the lifetime of carriers, characteristics of the diode portion 80 such as a reverse recovery time and a reverse recovery loss can be adjusted. A position at which the carrier lifetime shows a local minimum value in the depth direction of the semiconductor substrate 10 may be set as the depth position of the lifetime adjustment region 206.

Note that, if an electron beam, a particle ray and the like for forming the lifetime adjustment region 206 pass through the gate trench portion 40, defects may be formed in the vicinity of an interface between the gate dielectric film 42 and the semiconductor substrate 10. Then, if hydrogen absorbing metal such as Ti exists in the vicinity of the gate trench portion 40, diffusing hydrogen is absorbed to prevent hydrogen from terminating dangling bonds of the gate trench portion 40 so that the threshold voltage may be varied.

The lifetime adjustment region 206 of the present example is arranged in the front surface 21 side of the semiconductor substrate 10. Here, the front surface 21 side of the semiconductor substrate 10 refers to a region from the center position of the semiconductor substrate 10 in the depth direction to the front surface 21 of the semiconductor substrate 10. The lifetime adjustment region 206 of this example is arranged at a lower side than the lower end of the trench portion. In addition, when the lifetime adjustment region 206 is formed by irradiating a particle ray such as an electron beam having a high penetrating capability, lattice defects are formed from the front surface 21 of the semiconductor substrate 10 to the back surface 23 in a substantially uniform manner. In this case, the lifetime adjustment region 206 may also be considered to be arranged such that its depth position is in the front surface 21 side of the semiconductor substrate 10.

The lifetime adjustment region 206 may be provided in at least one of the transistor portion 70 and the diode portion 80. If the semiconductor device 100 includes the boundary region 200, the boundary region 200 may also be provided with the lifetime adjustment region 206. The lifetime adjustment region 206 may be provided to extend across at least a part of the diode portion 80 or the entire diode portion 80 in a first direction (the X axis direction.) The lifetime adjustment region 206 may be provided to extend across at least a part of the transistor portion 70 or the entire transistor portion 70 in the first direction (the X axis direction.) The lifetime adjustment region 206 may also be provided in the entire boundary region 200. In another example, the lifetime adjustment region 206 may be provided in a part of the boundary region 200.

The lifetime adjustment region 206 of the present example is provided to extend across the entire transistor portion 70 and diode portion 80 in the first direction (the X axis direction.) That is, the lifetime adjustment region 206 of the present example is provided to further extend across the entire boundary region 200 in the first direction (the X axis direction.)

As described above, the doping concentration of the anode region 84 of the present example is the same as the doping concentration of the base region 14. The semiconductor device 100 of the present example includes the lifetime adjustment region 206 to reduce the reverse recovery loss of the diode portion 80 such that the doping concentration of the anode region 84 can be increased to the same degree as that of the base region 14. Therefore, the base region 14 and the anode region 84 can be formed in the same process, which facilitates the fabrication.

In addition, the lifetime adjustment region 206 of the present example is provided to extend across the entire transistor portion 70 in the first direction (the X axis direction) such that the hole implantation from the contact region 15 of the transistor portion 70 can be reduced. Therefore, it may not be provided to extend across a plurality of mesa portions 60 of the boundary region 200 in the first direction (the X axis direction) such that an area of an invalid region where the transistor operation does not occur can be reduced.

The one or more gate trench portions 40 and the one or more dummy trench portions 30 are provided in the front surface 21 side of the semiconductor substrate 10. Each trench portion is provided to extend from the front surface 21 of the semiconductor substrate 10 to a position below the base region 14 and the anode region 84, through the base region 14 or the anode region 84. In a region where at least any of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

As described above, the transistor portion 70 is provided with the gate trench portion 40 and a dummy trench portion 30. The diode portion 80 and the boundary region 200 of this example are provided with the dummy trench portion 30, and are not provided with the gate trench portion 40. Note that the gate trench portion 40 may be arranged or the dummy trench portion 30 may be arranged at the boundary between the boundary region 200 and the transistor portion 70.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided inside the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the front surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 has a dummy trench, a dummy dielectric film 32, and a dummy conductive portion 34 that are provided at the front surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of the present example are covered with the interlayer dielectric film 38 at the front surface 21 of the semiconductor substrate 10. Note that the bottom portions of the dummy trench portion 30 and the gate trench portion 40 may be formed in a curved-surface shape (a curved shape in the cross section) convexly downward.

The first mesa portion 61 of the present example is provided with a first contact portion 77. In the first mesa portion 61, a region where the first mesa portion 61 and the front surface electrode are connected to each other in the first contact portion 77 corresponds to the contact portion.

The third mesa portion 63 of the present example is provided with a second contact portion 87 where the front surface electrode is in contact with the front surface of the third mesa portion 63. The second contact portion 87 is a portion of the front surface electrode (that is, the emitter electrode 52 or the contact plug portion) provided inside the mesa portion 60. A trench is formed on the front surface 21 of the semiconductor substrate 10 exposed by the contact hole 54 and filled up with the front surface electrode such that the second contact portion 87 can be formed. In the second contact portion 87, a region where the third mesa portion 63 and the front surface electrode are connected to each other corresponds to the contact portion. The first contact portion 77 is arranged at an upper side than the second contact portion 87.

The fourth mesa portion 64 of the present example is provided with the second contact portion 87. Alternatively, some fourth mesa portions 64 may be provided with the first contact portions 77 and other fourth mesa portions 64 may be provided with the second contact portions 87.

In the present example, each contact portion refers to an interface at which the front surface electrode and the mesa portion 60 are in contact. The contact portion may include a surface of the front surface electrode and a surface of the mesa portion 60. Here, in the case of the first contact portion 77, the surface of the mesa portion 60 refers to the front surface of the mesa portion 60, that is, the front surface 21 of the semiconductor substrate 10. In the case of the second contact portion 87, the surface of the mesa portion 60 refers to the bottom surface of the contact hole 54 provided inside the mesa portion 60.

Note that a metal silicide layer is formed at the interface between the front surface electrode and the mesa portion 60, the metal silicide layer may be included in the front surface electrode. That is, an interface between the metal silicide layer and the mesa portion 60 may be defined as a contact portion.

In the present example, the diode portion 80 is provided with the second contact portion 87 to remove a region having a higher doping concentration in the vicinity of the front surface 21 of the semiconductor substrate 10 such that the second contact portion 87 contacts with a region having a lower doping concentration in the anode region 84. This can decrease the reverse recovery loss of the diode portion 80.

FIG. 3B is an enlarged view showing in the vicinity of the contact hole 54 provided in the first mesa portion 61, the third mesa portion 63 and the fourth mesa portion 64 shown in FIG. 3A. FIG. 3B shows one first mesa portion 61, one third mesa portion 63 and one fourth mesa portion 64 and omits regions between the respective mesa portions.

The emitter electrode 52 of the present example is provided on the front surface of the interlayer dielectric film 38. The contact plug portion 250 includes a plug 251 and a barrier metal portion 252. The plug 251 of the present example includes tungsten. The barrier metal portion 252 is provided above the front surface 21 of the semiconductor substrate 10. The barrier metal portion 252 is provided at least on the bottom surface of the contact hole 54. The barrier metal portion 252 may be provided on each contact portion. The barrier metal portion 252 may be in contact with the semiconductor substrate 10. The barrier metal portion 252 may also be provided on the side surface of the contact hole 54. The plug 251 is embedded in the contact hole 54 via the barrier metal portion 252. The plug 251 and the barrier metal portion 252 may also be provided or may not be provided on the front surface of the interlayer dielectric film 38.

The barrier metal portion 252 reduces ions included in a metal element of the plug 251 or the external environment entering into the semiconductor substrate 10. The barrier metal portion 252 may include at least one metal element of titanium (Ti), cobalt (Co), nickel (Ni), tantalum (Ta), magnesium (Mg), vanadium (V), lanthanum (La), palladium (Pd) or zirconium (Zr). The barrier metal portion 252 may be a hydrogen absorbing metal. The barrier metal portion 252 of the present example includes a titanium (Ti) layer. The barrier metal portion 252 may include a titanium nitride layer. The barrier metal portion 252 may be a stacked film of a titanium layer and a titanium nitride layer.

The emitter electrode 52 is provided above the barrier metal portion 252. The emitter electrode 52 is also provided above the interlayer dielectric film 38. The emitter electrode 52 is formed of a material different from that of the barrier metal portion 252. As an example, the emitter electrode 52 includes aluminum. The emitter electrode 52 may be an alloy of aluminum and silicon.

FIG. 3B shows a depth Z1 of the first contact portion 77 and a depth Z2 of the second contact portion 87 in the depth direction (the Z axis direction) of the semiconductor substrate 10. In the present example, the first mesa portion 61 is provided with the first contact portion 77 and the third mesa portion 63 and the fourth mesa portion 64 are provided with the second contact portion 87.

Here, the depths of the first contact portion 77 and the second contact portion 87 refer to distances from the front surface 21 of the semiconductor substrate 10 to the deepest position of the interface at which the semiconductor substrate 10 and the front surface electrode are in contact on the bottom surface of the contact hole 54. The depth Z2 of the second contact portion 87 is greater than the depth Z1 of the first contact portion 77.

The first contact portion 77 of the present example is in contact with the front surface 21 of the semiconductor substrate 10. Therefore, the depth Z1 of the first contact portion 77 is zero. The first contact portion 77 may be arranged at a position deeper than that of the front surface 21 of the semiconductor substrate 10. In addition, the depth Z2 of the second contact portion 87 of the present example is larger than the depth Z1 the first contact portion 77. That is, the second contact portion 87 is arranged at a position more distant from the front surface 21 of the semiconductor substrate 10 than the first contact portion 77.

In the present example, the transistor portion 70 is provided with the first contact portion 77 such that a surface area (a total area of the side surface and the bottom surface) of the contact hole 54 provided in the transistor portion 70 is smaller than a surface area of the contact hole 54 provided in the diode portion 80. Therefore, in the contact hole 54 provided in the transistor portion 70, an area of the barrier metal portion 252 is relatively small, whereby an amount of the Ti layer in the barrier metal portion 252 is relatively small. This can reduce a variance of the threshold voltage caused by the hydrogen absorbing Ti layer.

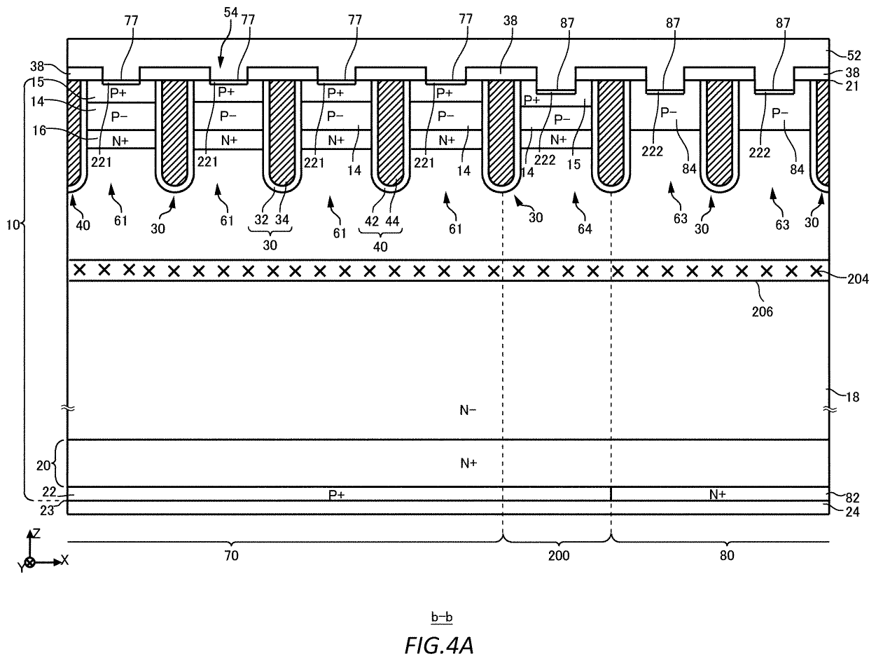

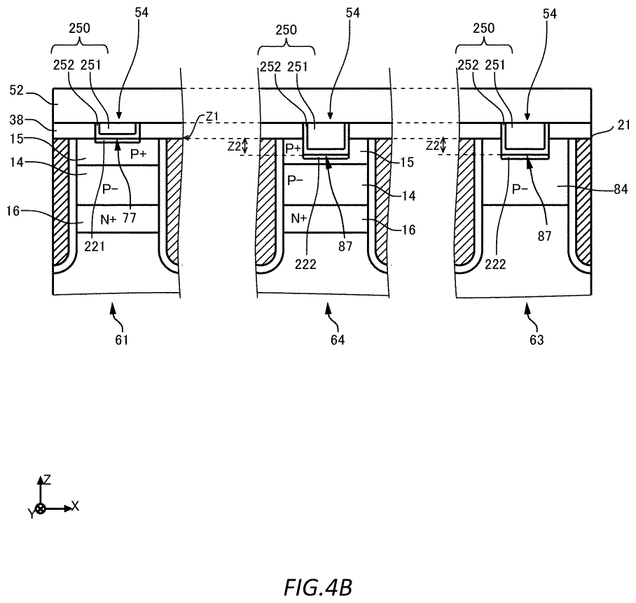

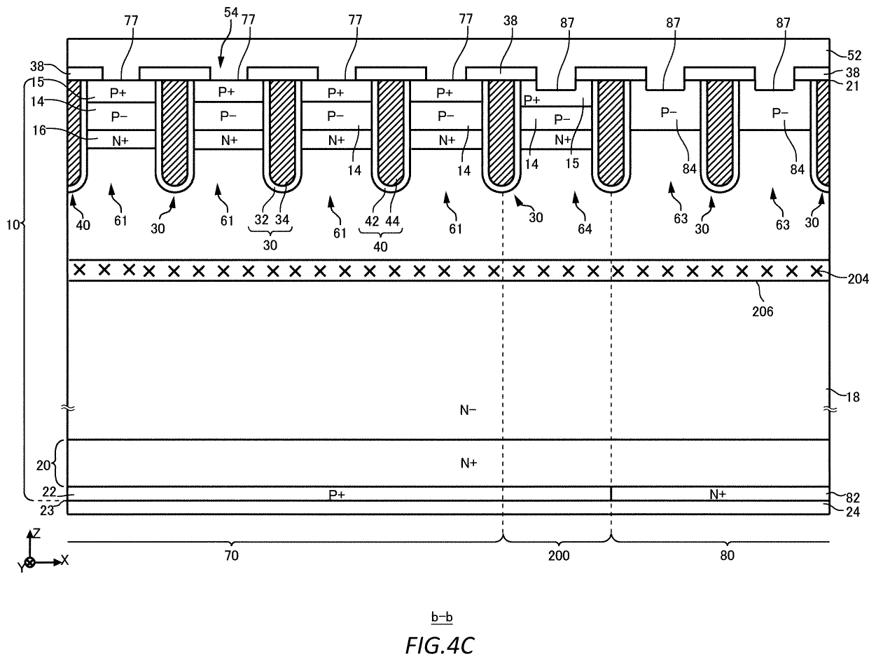

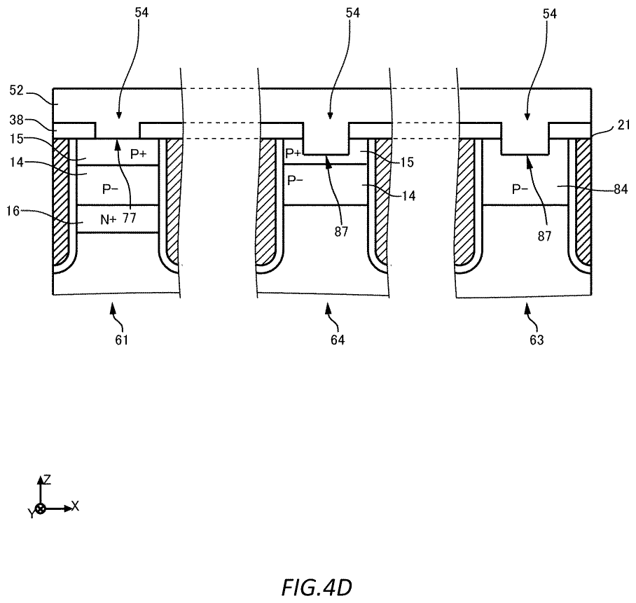

FIG. 4A is a diagram showing an example of a cross section b-b in FIG. 2. The cross section b-b is an XZ plane passing through the contact region 15 and the cathode region 82. On the cross section b-b of FIG. 4A, the contact region 15 is arranged instead of the emitter region 12 on the cross section a-a shown in FIG. 3A. In addition, a plug region of the second conductivity type is provided below the contact hole 54. Other structures will not be described here as they are similar to those on the cross section a-a.

The first mesa portion 61 of the present example is provided below the first contact portion 77 and includes a first plug region 221 of a P++type having a doping concentration higher than that of the contact region 15. The first plug region 221 may be provided in contact with the first contact portion 77. At least a part of the first plug region 221 is provided to overlap with the contact region 15 in a top plan view. The entire first plug region 221 may be provided to overlap the contact region 15. That is, the first plug region 221 is provided on any of the XZ cross sections passing through the contact region 15. The first plug region 221 may be provided on the XZ cross section passing through the center of the contact region 15 in the Z axis direction.

In the present example, as can be seen from FIG. 3A, the XZ cross section passing through the emitter region 12 is not provided with the first plug region 221. That is, the first plug region 221 is provided below the contact region 15 and may not be provided below the emitter region 12. For example, the XZ cross section passing through the center of the emitter region 12 in the Z axis direction is not provided with the first plug region 221. That is, the first plug regions 221 do not overlap with the emitter regions 12 in a top plan view, and the first plug regions 221 are provided discretely in the second direction (the Y axis direction.)

Each plug region is provided to facilitate to extract holes in each mesa portion. For this reason, it is possible to suppress reduction in withstand capability. In another example, the first plug region 221 may also be provided below the emitter region 12 or may also be provided to extend in the second direction (the Y axis direction), unless it does not prevent the connection of the emitter region 12 and the first contact portion 77 at all.

The third mesa portion 63 is provided below the second contact portion 87 and may include a second plug region 222 of the P++type having a doping concentration higher than that of the contact region 15. The second plug region 222 may be provided in contact with the second contact portion 87.

Alternatively, similarly to the first plug regions 221 described above, the second plug regions 222 are not provided on the XZ cross section passing through the emitter region 12 and may be provided discretely below the contact regions 15 in the second direction (the Y axis direction). The second plug regions 222 of the present example are provided discretely in the second direction (the Y axis direction), similarly to the first plug regions 221, and are not provided on the XZ cross section passing through the center of the emitter region 12 in the Z axis direction. This can reduce the hole implantation from the third mesa portion 63 to the drift region 18 to reduce the reverse recovery loss.

In another example, the second plug regions 222 of the third mesa portions 63 provided discretely in the second direction (the Y axis direction) may be provided to have the interval, width, or positions different from the interval, width, or positions of the emitter regions 12 of the first mesa portion 61. The second plug regions 222 of each third mesa portion 63 may be provided to have the interval, width, or positions different from those of the second plug regions 222 of another third mesa portion 63. The second plug region 222 may be provided to extend in the second direction (the Y axis direction.)

The fourth mesa portion 64 may include the second plug region 222 below the second contact portion 87. The configuration of the second plug region 222 in the fourth mesa portion 64 is the same as the configuration of the second plug region 222 in the third mesa portion 63, and thus will not be described.

FIG. 4B is an enlarged view showing in the vicinity of the contact hole 54 provided in the first mesa portion 61, the third mesa portion 63 and the fourth mesa portion 64 shown in FIG. 4A. In the present example, the first plug region 221 is provided below the first contact portion 77 and the second plug region 222 is provided below the second contact portion 87, while other points are the same as those in FIG. 3B and thus will not be described. Each plug region is provided to facilitate to extract holes in each mesa portion. For this reason, it is possible to suppress reduction in withstand capability.

FIG. 4C is a diagram showing another example of the cross section b-b in FIG. 2. FIG. 4D is an enlarged view showing in the vicinity of the contact hole 54 provided in the first mesa portion 61, the third mesa portion 63 and the fourth mesa portion 64 shown in FIG. 4C. In the present example, the first plug region 221 and the second plug region 222 are not provided below the contact region 15 and the anode region 84. That is, the semiconductor device 100 of the present example is not provided with the plug region. This can reduce the hole implantation to reduce the reverse recovery loss.

Note that, if the plug region is not provided, both of the first contact portion 77 and the second contact portion 87 are not provided with the contact plug portion 250, that is, the plug 251 and the barrier metal portion 252, and similarly, a position at which the first contact portion 77 is in contact with the emitter region 12 is not provided with the plug 251 and the barrier metal portion 252.

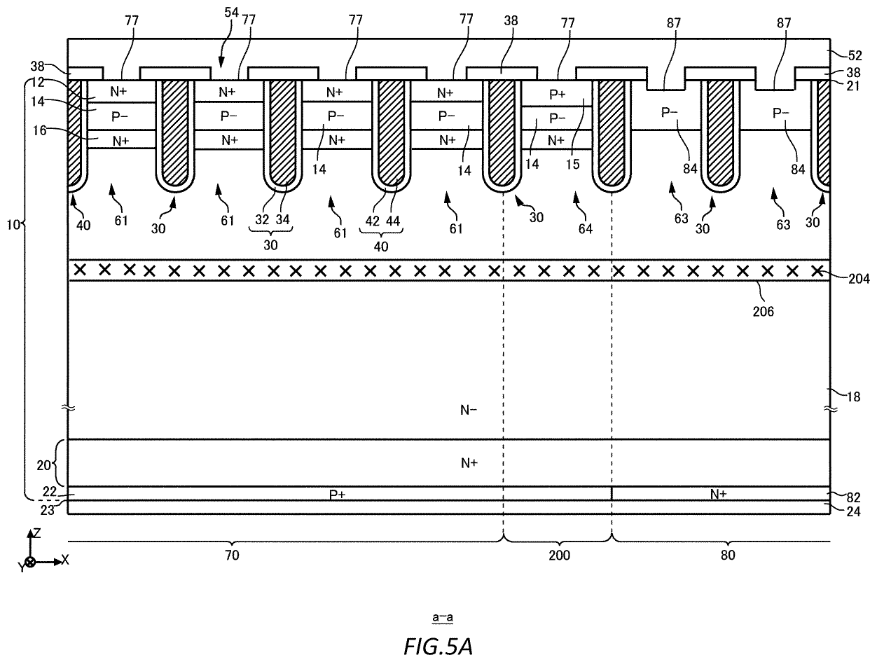

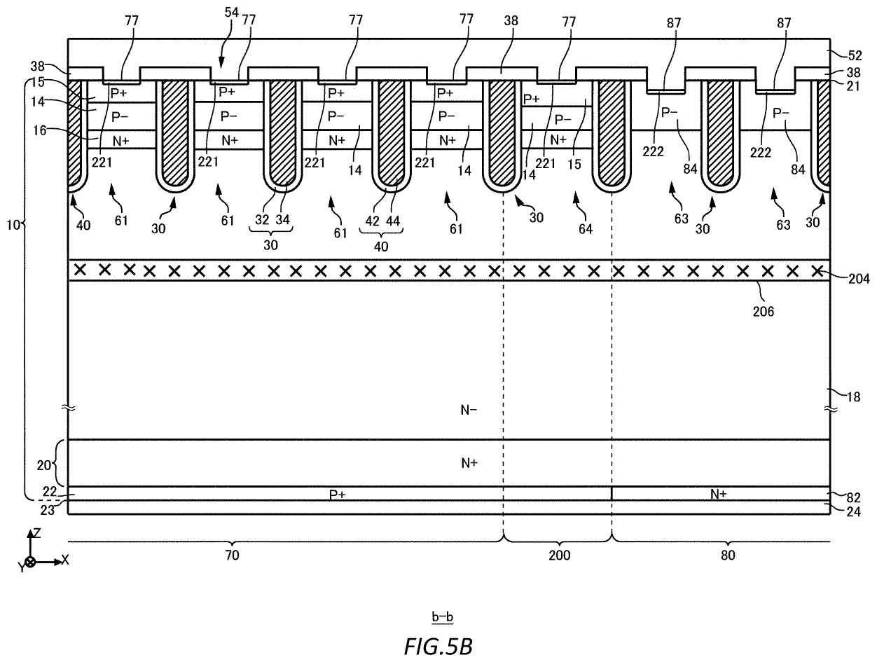

FIG. 5A is a diagram showing another example of the cross section a-a in FIG. 2. FIG. 5B is a diagram showing another example of the cross section b-b in FIG. 2. In the present example, the fourth mesa portion 64 of the boundary region 200 provided with the second contact portion 87 instead of the first contact portion 77 is different from that of the example described above. Therefore, the fourth mesa portion 64 of the boundary region 200 is provided with the first plug region 221 below the first contact portion 77.

The first plug regions 221 of the fourth mesa portion 64 of the present example may be provided in the arrangement similar to that of the second plug regions 222 of the fourth mesa portion 64 described by use of FIG. 4A. Such a configuration can also obtain an effect similar to that of the configuration described above.

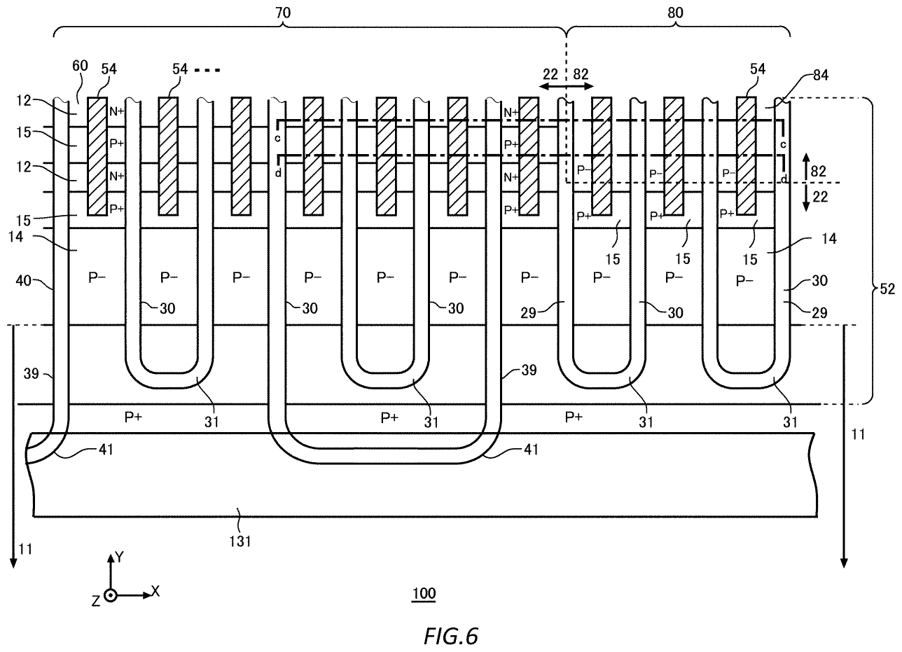

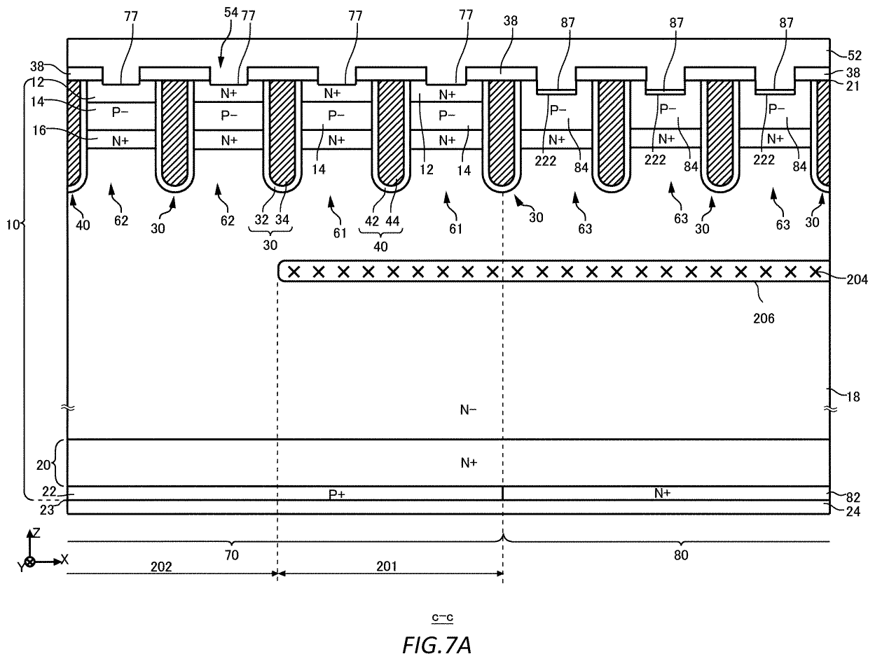

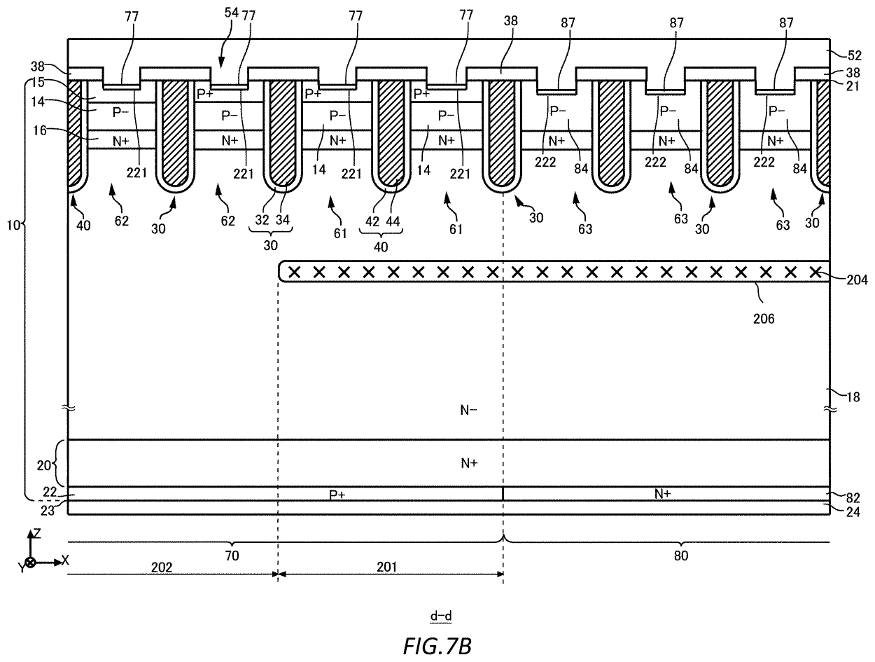

FIG. 6 is an enlarged view showing another example of the region D in FIG. 1. FIG. 7A is a diagram showing an example of a cross section c-c in FIG. 6. FIG. 7B is a diagram showing an example of a cross section d-d in FIG. 6. The present example is different from the example described above in that the boundary region 200 is not provided between the transistor portion 70 and the diode portion 80.

In addition, the lifetime adjustment region 206 of the present example is provided to extend across the diode portion 80 and a part of the transistor portion 70 in the second direction (the Y axis direction.)

The semiconductor device 100 of the present example includes the lifetime adjustment region 206 at least in a part of the transistor portion 70 such that an area of an invalid region where the transistor operation does not occur can be reduced by omitting a broad boundary region 200. An example of providing a broad boundary region 200 will be described below. In the transistor portion 70, a region provided with the lifetime adjustment region 206 is defined as an adjustment region 201 and a region not provided with the lifetime adjustment region 206 is defined as a no-adjustment region 202. The configuration of the diode portion 80 is the same as that of the example described above and this will not be described.

The adjustment region 201 of the present example includes the first contact portion 77 provided in the first mesa portion 61. A part of the first mesa portions 61 may be provided with the first contact portions 77 or all of the first mesa portions 61 may be provided with the first contact portions 77. Alternatively, all of the first mesa portions 61 may be provided with the second contact portions 87. The first mesa portion 61 of the adjustment region 201 has the same structure as that of the first mesa portion 61 described above and thus will not be described.

The no-adjustment region 202 of the present example includes the first contact portion 77 provided in the second mesa portion 62. The no-adjustment region 202 is a region where a carrier lifetime at the same depth position as the lifetime adjustment region 206 is longer than a carrier lifetime of the lifetime adjustment region 206 of the diode portion 80. The no-adjustment region 202 may be a region where charged particles such as helium for forming lifetime killers such as the lattice defects 204 are not implanted. A chemical concentration (/cm³) of the charged particles such as helium in the no-adjustment region 202 may be the same as a chemical concentration of the charged particles at the center of the drift region 18 in the Z axis direction.

The first contact portion 77 of the present example is arranged at a lower side than the front surfaces of the first mesa portion 61 and the second mesa portion 62. A depth of the first contact portion 77 may be a depth equal to or smaller than ½ or may be a depth equal to or smaller than ¼ of a depth of the second contact portion 87. The first contact portion 77 may be in contact with the front surface 21 of the semiconductor substrate 10 and the depth Z1 of the first contact portion 77 may be zero.

A doping concentration of the anode region 84 of the present example may be the same as a doping concentration of the base region 14. The semiconductor device 100 of the present example includes the lifetime adjustment region 206 to reduce the reverse recovery loss of the diode portion 80 such that the doping concentration of the anode region 84 can be increased to the same degree as that of the base region 14. Therefore, the base region 14 and the anode region 84 can be formed in the same process, which facilitates the fabrication. In another example, the doping concentration of the anode region 84 may be lower than the doping concentration of the base region 14 such that the reverse recovery loss can further be reduced.

In addition, the second plug region 222 of the present example is provided to extend in the second direction (the Y axis direction.)

The semiconductor device 100 of the present example includes the lifetime adjustment region 206 to reduce the reverse recovery loss of the diode portion 80 such that the second plug region 222 can be provided to extend to facilitate to extract holes and suppress reduction in withstand capability.

Note that, in another example, the plug regions may be provided discretely as described in FIG. 3A, FIG. 3B, FIG. 4A and FIG. 4B, or may not be provided as described in FIG. 4C and FIG. 4D.

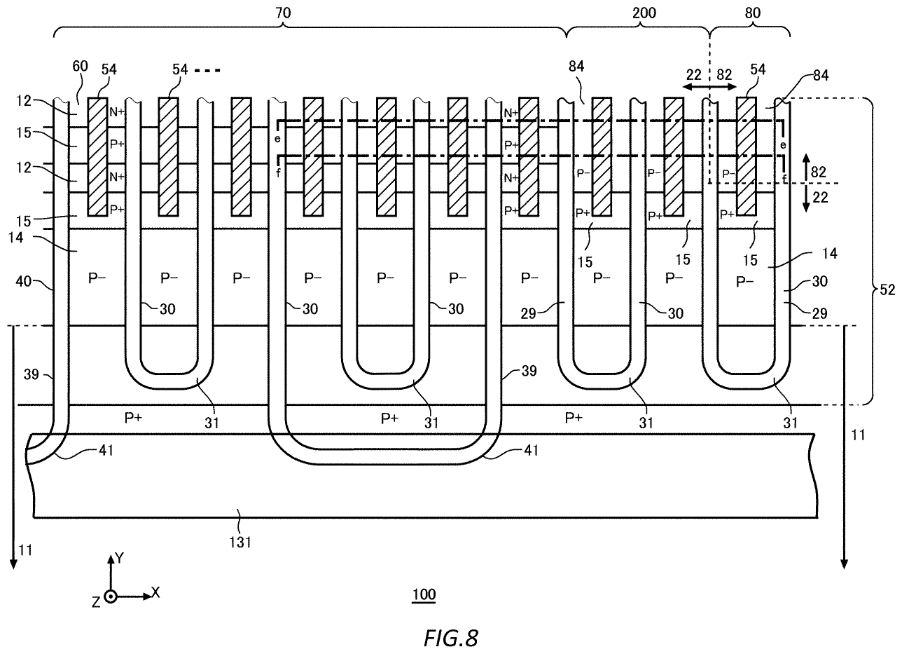

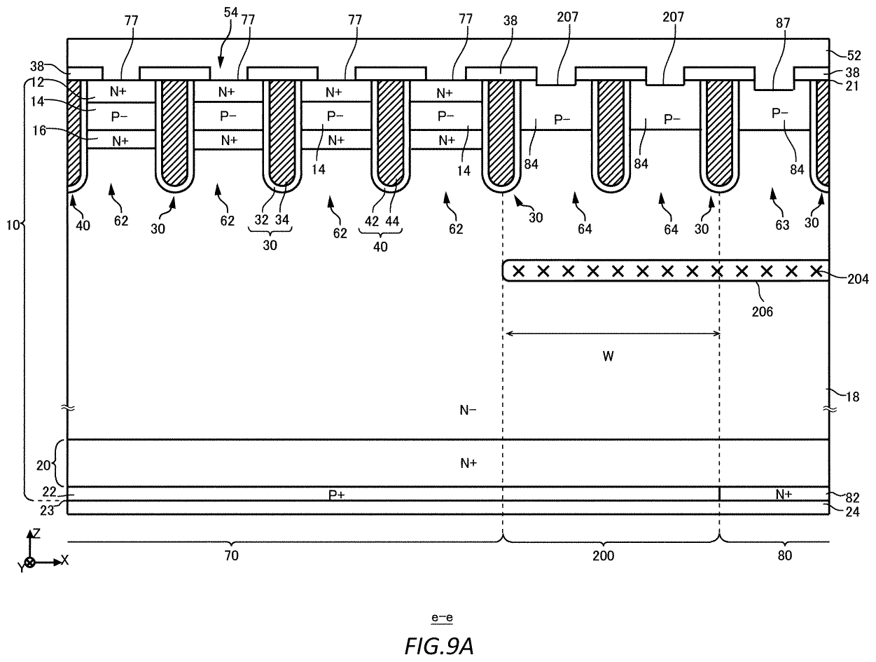

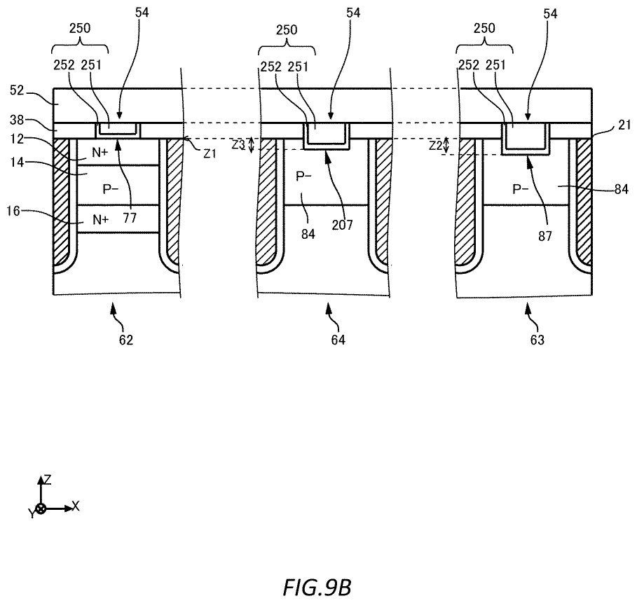

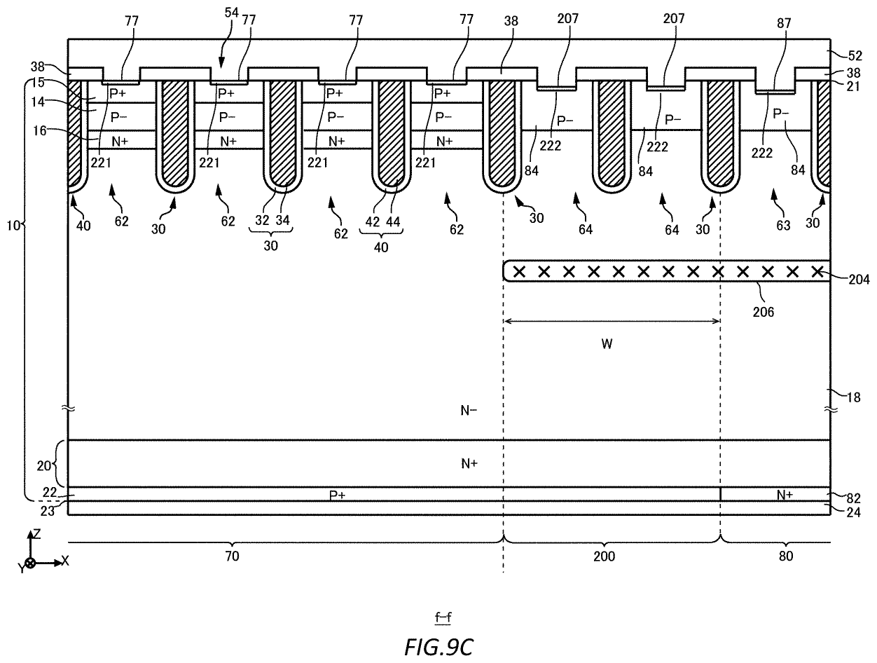

FIG. 8 is an enlarged view showing another example of the region D in FIG. 1. FIG. 9A is a diagram showing an example of a cross section e-e in FIG. 8. FIG. 9B is an enlarged view in the vicinity of the second mesa portion 62, the third mesa portion 63 and the fourth mesa portion 64 shown in FIG. 9A. FIG. 9C is a diagram showing an example of a cross section f-f in FIG. 8.

A width of the boundary region 200 of the present example is greater than a width of the boundary region 200 shown in FIG. 2. The width W of the boundary region 200 of the present example in the first direction (the X axis direction) may be equal to or greater than 20 μm and equal to or smaller than 250 μm, preferably, is equal to or greater than 30 μm and equal to or smaller than 200 μm, and more preferably, equal to or greater than 50 μm and equal to or smaller than 100μm.

The lifetime adjustment region 206 of the present example is provided to extend from the diode portion 80 to the boundary region 200 in the first direction (the X axis direction.) That is, the lifetime adjustment region 206 of the present example is not provided in the transistor portion 70. Alternatively, the semiconductor device 100 may not include the lifetime adjustment region 206.

In the present example, the broad boundary region 200 is provided across a plurality of fourth mesa portions 64 such that the transistor portion 70 can be prevented from affecting the characteristics of the diode portion 80, for example, the operation of the gate trench portion 40 and the discharge or injection of holes of the contact region 15 can be prevented from affecting the forward voltage and the reverse recovery characteristics. Therefore, the lifetime adjustment region 206 of the present example may not be provided in the transistor portion 70.

The boundary region 200 of the present example is provided with the third contact portion 207 in the fourth mesa portion 64. As shown in FIG. 9B, the third contact portion 207 is arranged at an upper side than the second contact portion 87 and arranged at a lower side than the first contact portion 77. That is, the depth Z3 of the third contact portion 207 is greater than the depth of the first contact portion 77 and smaller than the depth Z2 of the second contact portion 87. The depth Z3 of the third contact portion 207 may be a depth equal to or smaller than ½ or may be a depth equal to or smaller than ¼ of the depth Z2 of the second contact portion 87. In this manner, in the present example, the boundary region 200 is provided with a relatively shallow third contact portion 207 to facilitate to extract holes to prevent the latch up while reducing the amount of Ti layer of the barrier metal portion 252.

In another example, as described in FIG. 3A, FIG. 3B, FIG. 4A and FIG. 4B, the boundary region 200 may be provided with the first contact portion 77 or may be provided with the second contact portion 87. In addition, in the examples described using FIG. 2 to FIG. 5B, the boundary region 200 may also be provided with the third contact portion 207 of the present example.

The boundary region 200 of the present example is provided with the anode region 84 on the front surface of the fourth mesa portion 64 and not provided with the contact region 15. That is, the structure of the front surface of the fourth mesa portion 64 is the same as the structure of the front surface of the third mesa portion 63. In addition, the doping concentration of the anode region 84 of the present example is lower than the doping concentration of the base region 14. In another example, the doping concentration of the anode region 84 may be the same as the doping concentration of the base region 14.

In addition, in FIG. 9A and FIG. 9C, the first plug region 221 and the second plug region 222 are provided on the XZ cross section passing through the contact region 15 and not provided on the XZ cross section passing through the emitter region 12. Therefore, the first plug regions 221 and the second plug regions 222 of the present example are provided discretely in the second direction (the Y axis direction.) This reduces the implantation of holes such that the reverse recovery loss can be reduced even if the width W of the lifetime adjustment region 206 is small. Note that, in another example, the plug regions may be provided discretely or continuously as described in FIG. 3A, FIG. 3B, FIG. 4A and FIG. 4B, or may not be provided as described in FIG. 4C and FIG. 4D.

While the present invention has been described with the embodiments, the technical scope of the present invention is not limited to the above-described embodiments. It is apparent to persons skilled in the art that various alterations and improvements can be added to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 11: well region, 12: emitter region, 14: base region, 15: contact region, 16: accumulation region, 18: drift region, 20: buffer region, 21: front surface, 22: collector region, 23: back surface, 24: collector electrode, 29: linear portion, 30: dummy trench portion, 31: edge portion, 32: dummy dielectric film, 34: dummy conductive portion, 38: interlayer dielectric film, 39: linear portion, 40: gate trench portion, 41: edge portion, 42: gate dielectric film, 44: gate conductive portion, 52: emitter electrode, 54: contact hole, 60: mesa portion, 61: first mesa portion, 62: second mesa portion, 63: third mesa portion, 64: fourth mesa portion, 70: transistor portion, 77: first contact portion, 80: diode portion, 81: extension region, 82: cathode region, 84: anode region, 87: second contact portion, 90: edge termination structure portion, 100: semiconductor device, 130: outer circumferential gate runner, 131: active-side gate runner, 160: active portion, 162: end side, 164: gate pad, 200: boundary region, 201: adjustment region, 202: no-adjustment region, 204: lattice defect, 206: lifetime adjustment region, 207: third contact portion, 221: first plug region, 222: second plug region, 250: contact plug portion, 251: plug, 252: barrier metal portion

What is claimed is:

1. A semiconductor device, comprising:
a transistor portion;
a diode portion;
a plurality of trench portions provided on a front surface of a semiconductor substrate;
a drift region of a first conductivity type provided in the semiconductor substrate;
a base region of a second conductivity type provided above the drift region in the transistor portion;
an emitter region of the first conductivity type provided on the front surface of the semiconductor substrate in the transistor portion and having a doping concentration higher than that of the drift region;
a contact region of the second conductivity type having a doping concentration higher than that of the base region;
an anode region of the second conductivity type provided above the drift region in the diode portion;
a mesa portion of the semiconductor substrate provided between the plurality of trench portions;
an interlayer dielectric film provided above the semiconductor substrate;
a front surface electrode provided above the semiconductor substrate;
a contact portion at which the front surface electrode and the mesa portion are connected to each other in a contact hole of the interlayer dielectric film; and
a lifetime adjustment region provided in a front surface side of the semiconductor substrate,
wherein the contact portion includes a first contact portion provided in the transistor portion and a second contact portion provided in the diode portion, and
wherein the first contact portion is arranged at an upper side than the second contact portion.

2. The semiconductor device according to claim 1, comprising:
a second plug region of the second conductivity type provided below the second contact portion and having a doping concentration higher than that of the contact region.

3. The semiconductor device according to claim 2, wherein
the second plug region is provided to extend in a trench extending direction.

4. The semiconductor device according to claim 2, wherein
the second plug region is provided discretely in a trench extending direction.

5. The semiconductor device according to claim 1, comprising:
a first plug region of the second conductivity type provided below the first contact portion and having a doping concentration higher than that of the contact region.

6. The semiconductor device according to claim 5, wherein
the first plug region is provided discretely in a trench extending direction.

7. The semiconductor device according to claim 5, wherein
the first plug region is provided above the contact region and not provided above the emitter region.

8. The semiconductor device according to claim 1, comprising:
a barrier metal portion provided on a side surface of the contact hole,
wherein the barrier metal portion includes a Ti layer.

9. The semiconductor device according to claim 1, comprising:
an accumulation region of the first conductivity type provided above the drift region in the transistor portion and having a doping concentration higher than that of the drift region.

10. The semiconductor device according to claim 1, wherein
the front surface electrode includes an emitter electrode provided above the interlayer dielectric film.

11. The semiconductor device according to claim 10, wherein
the front surface electrode includes a contact plug portion provided in the contact hole and connecting the emitter electrode and the mesa portion.

12. The semiconductor device according to claim 1, wherein
the diode portion includes the lifetime adjustment region.

13. The semiconductor device according to claim 1, wherein
the transistor portion includes the lifetime adjustment region.

14. The semiconductor device according to claim 13, wherein
the lifetime adjustment region of the transistor portion is formed by irradiating a particle ray.

15. The semiconductor device according to claim 13, wherein
the lifetime adjustment region is provided to extend in a trench array direction across the entire transistor portion and the diode portion.

16. The semiconductor device according to claim 13, wherein
the lifetime adjustment region is provided to extend in a trench array direction from the diode portion to a part of the transistor portion.

17. The semiconductor device according to claim 1, wherein
a doping concentration of the anode region is lower than a doping concentration of the base region.

18. The semiconductor device according to claim 1, wherein
a doping concentration of the anode region is the same as a doping concentration of the base region.

19. The semiconductor device according to claim 1, wherein
the first contact portion is in contact with a front surface of the mesa portion.

20. The semiconductor device according to claim 1, wherein
the first contact portion is arranged at a lower side than a front surface of the mesa portion.

21. The semiconductor device according to claim 1, comprising:
a boundary region provided between the transistor portion and the diode portion.

22. The semiconductor device according to claim 21, wherein
the lifetime adjustment region is provided to extend in a trench array direction from the diode portion to the boundary region.

23. The semiconductor device according to claim 21, wherein
a width of the boundary region in a trench array direction is equal to or greater than 20 μm and equal to or smaller than 250 μm.

24. The semiconductor device according to claim 21, wherein
the contact portion in the boundary region is a third contact portion, and
the third contact portion is arranged at an upper side than the second contact portion and arranged at a lower side than the first contact portion.

25. The semiconductor device according to claim 21, wherein
the contact portion of the boundary region is the second contact portion.
